(19) United States
(12) Patent Application Publication
(10) Pub. No.: US 2005/0253138 A1
(43) Pub. Date: Nov. 17, 2005

(54) Silicon optoelectronic device using silicon nanowire and method for preparing the same

(76) Inventors: Heon Jin Choi, Seoul (KR); Jung-Chul Lee, Gyeonggi-do (KR); Young Ju Park, Seoul (KR); Jae Gwan Park, Seoul (KR)

Correspondence Address: WHITHAM, CURTIS & CHRISTOFFERSON, P.C., 11491 SUNSET HILLS ROAD, SUITE 340, RESTON, VA, 20190, US

(21) Appl. No.: 11/012,698

(22) Filed: Dec. 16, 2004

(30) Foreign Application Priority Data
Apr. 23, 2004 (KR) 10-2004-0028397

(51) Int. Cl. H01L 29/08

(52) U.S. Cl. 257/40

(57) ABSTRACT

The present invention relates to a silicon optoelectronic device using silicon nanowire and a method for preparing the same. More particularly, the present invention relates to a silicon optoelectronic device using silicon nanowire, which is prepared by doping erbium (Er) into silicon nanowire and form a silicon dioxide sheath on the surface of the silicon nanowire by oxidation, so that the diameter of the silicon nanowire is reduced to give quantum confinement effect and photoelectric transition effect, and a method for preparing the same. When an electric current is applied, light emitted by the photoelectric transition effect of the silicon nanowire excites and decays the doped erbium to effectively emit light having a wavelength of about 1.5 μm. The silicon dioxide sheath effectively amplifies the light by the microcavity effect of the silicon nanowire.

### CROSS REFERENCE TO RELATED APPLICATION

This application is based on, and claims priority from Korean Patent Application No. 2004-0028397, filed on Apr. 23, 2004, the disclosure of which is hereby incorporated by reference.

### BACKGROUND OF THE INVENTION

1. Field of the Invention

The present invention relates to a silicon optoelectronic device using silicon nanowire and a method for preparing the same, more particularly to a silicon optoelectronic device using silicon nanowire, which is prepared by doping erbium (Er) into silicon nanowire and form a silicon dioxide sheath on the surface of the silicon nanowire by oxidation, so that the diameter of the silicon nanowire is reduced to give quantum confinement effect and photoelectric transition effect, and a method for preparing the same. When an electric current is applied, light emitted by the photoelectric transition effect of the silicon nanowire excites and decays the doped erbium to effectively emit light having a wavelength of about 1.5 μm. The silicon dioxide sheath effectively amplifies the light by the microcavity effect of the silicon nanowire.

2. Description of the Related Art

When a semiconductor material has a size smaller than the Bohr exciton radius, it results in having several quantum confinement effects and researches have been actively carried out to develop devices using these phenomena.

As a typical example, a quasi direct band gap property appears when the size of silicon, which has the indirect band gap property, is reduced to several nanometers or less. A variety of optoelectronic devices are being developed using this property.

Erbium-doped semiconductor has become the topic of numerous researches because it emits light having a wavelength of about 1.5 μm, which can be utilized in optical communication by excitation and decay of erbium. Especially, if erbium is doped into silicon to obtain light having a wavelength of the above-mentioned wavelength, significant industrial and technical advantages are expected to be achieved considering that most of the currently used devices are made of silicon.

In this regard, many lines of studies have been carried out on erbium-doped silicons. However, they are mostly centered on amorphous, porous or quantum dot silicons.

The erbium-doped silicon transfers energy and excites the erbium. Then, the silicon emits light having a wavelength of about 1.5 μm by decay of the erbium. Until now, it has been known that the light has a weak intensity to be actually utilized in optoelectronic devices.

### SUMMARY OF THE INVENTION

The present inventors have worked to solve the aforementioned problem. In doing so, they found that when erbium is doped into silicon nanowire and the silicon nanowire is oxidized to form a silicon dioxide sheath on the surface, light having a diameter of about 1.5 μm wavelength is emitted effectively and that the intensity of the light can be enhanced by the photon amplification effect by the microcavity, which is formed by the silicon dioxide sheath.

Thus, it is an object of the present invention to provide an erbium-doped silicon optoelectronic device using silicon nanowire having improved light intensity and a method for preparing the same.

### BRIEF DESCRIPTION OF THE DRAWINGS

FIG. 1 is a schematic diagram showing an embodiment of the silicon nanowire optoelectronic device according to the present invention.

FIG. 2 is a scanning electron micrograph of the silicon nanowire formed on the silicon substrate of Example 1 of the present invention.

FIG. 3 is a graph showing the compositional analysis of the erbium-doped silicon nanowire of Example 1 of the present invention.

FIG. 4 is a graph showing the change of the thickness of the silicon and the silicon dioxide sheath according to the oxidation progress.

FIG. 5 is a transmission electron micrograph showing the oxidized silicon nanowire surface of Example 1 of the present invention.

FIG. 6 is the light emission spectrum of the optoelectronic device prepared in Example 1 of the present invention.

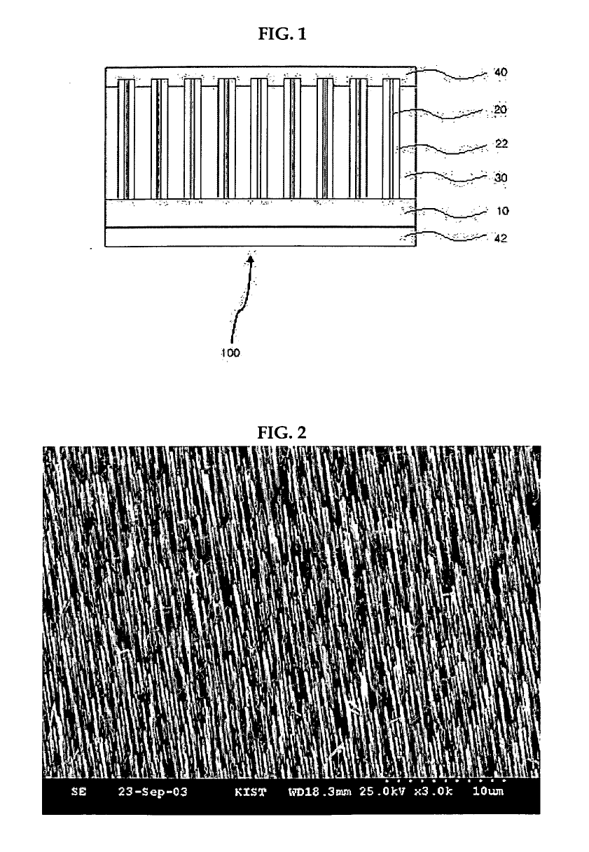

### DETAILED DESCRIPTION OF THE PREFERRED EMBODIMENTS

The present invention relates to silicon optoelectronic device 100 comprising n-type or p-type semiconductor substrate 10; silicon nanowire 20, which is formed on one side of the substrate, having a conductivity by a p-type or n-type dopant and erbium; an insulating film 30, which is formed on substrate 10, enclosing nanowire 20; first electrode 40, which is formed on silicon nanowire 20, a part of which has been exposed by etching, and enables electrical connection of silicon nanowire 20; and second electrode 42, which is formed on one side of substrate 10 and enables electrical connection of the exposed silicon nanowire 20 and the substrate 10.

The present invention is also characterized by a method for preparing a silicon optoelectronic device comprising the steps of depositing gold (Au) on an n-type or p-type semiconductor substrate and flowing a silicon-containing precursor on the substrate at 400-1,000° C. to form silicon nanowire; doping a p-type or n-type dopant and erbium or a precursor thereof into the silicon nanowire to offer conductivity; oxidizing the silicon nanowire at 300-1,000° C. to form a silicon dioxide sheath on the surface of the silicon nanowire; forming an insulating film which encloses the silicon nanowire on the substrate; etching the substrate to expose a part of the silicon nanowire; and forming first and second electrodes to enable electrical connection of the substrate and the exposed silicon nanowire.

Hereunder is given a more detailed description of the present invention.

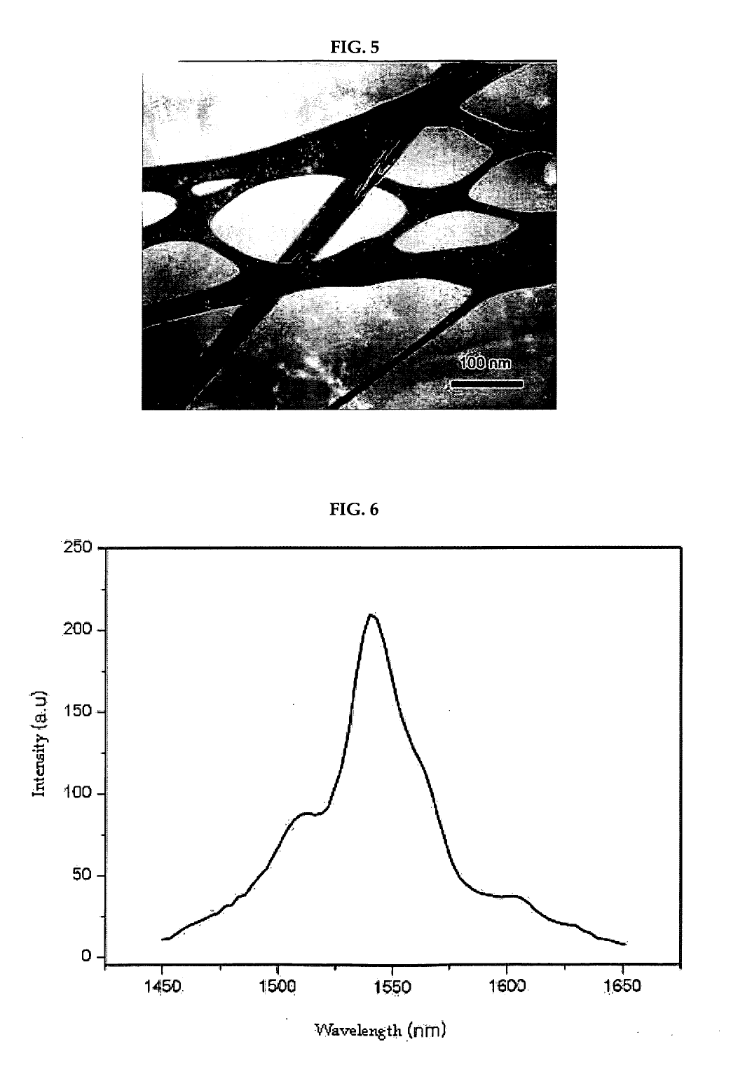

When erbium is doped into silicon nanowire and the silicon nanowire is oxidized to form a silicon dioxide sheath on the surface, the diameter of the silicon nanowire is reduced (see FIG. 5) to offer quantum confinement effect and photoelectric transition effect. When an electric current is applied, light emitted by the photoelectric transition effect of the silicon nanowire excites and decays the doped erbium to effectively emit light having a wavelength of about 1.5 μm. The silicon dioxide sheath effectively amplifies the light by the microcavity effect of the silicon nanowire. This phenomenon can be utilized in preparing an optoelectronic device.

The silicon optoelectronic device and the preparation method thereof of the present invention are described in detail with reference to the appended drawings.

Substrate 10 of silicon optoelectronic device 100 of the present invention is made of a silicon-containing semiconductor selected from, for example, Si, SiC, GaN and GaAs. It is doped to have an n-type or p-type property.

Au is deposited on the n-type or p-type semiconductor substrate 10 and a silicon-containing precursor is flown on the substrate at 400-1,000° C. to form silicon nanowire 20. Au nanoparticles are positioned on the substrate or an Au film having a nano size thickness is coated on the substrate to deposit Au. When Au is deposited at 400-1,000° C. and the silicon-containing precursor is flown on the substrate, silicon nanowire is formed on the catalytic action of the Au particles deposited on the substrate. The diameter of such formed silicon nanowire 20 is determined by the size of the Au particles deposited on the substrate. Therefore, it is preferable to position Au nanoparticles having a size of 10-100 nm on the substrate or to coat an Au film having a thickness of 1-10 nm in order to obtain silicon nanowire having an ideal diameter. FIG. 2 is a scanning electron micrograph of the silicon nanowire formed on the silicon substrate according to the present invention.

Silicon nanowire 20 must have an electrical characteristic opposed to that of substrate 10 for p-n junction. For this purpose, n-type or p-type silicon nanowire 20 is prepared by doping it with a p-type or n-type dopant. The dopant may be B or P. The resultant n-type or p-type silicon nanowire 20 is formed on one side of substrate 10 and is capable of forming p-n junction with substrate 10.

The doping of erbium or an erbium precursor may be performed during or after growth of silicon nanowire 20.

That is to say, erbium-doped silicon nanowire 20 may be prepared by adding an erbium precursor as silicon nanowire 20 grows on substrate 10 or by doping erbium on the surface of silicon nanowire 20 after it has grown. The doping may be performed by a method selected from, for example, wet method, sol-gel method, coprecipitation, chemical deposition, laser abrasion and sputtering. Specifically, the erbium precursor may be ErCl₃.

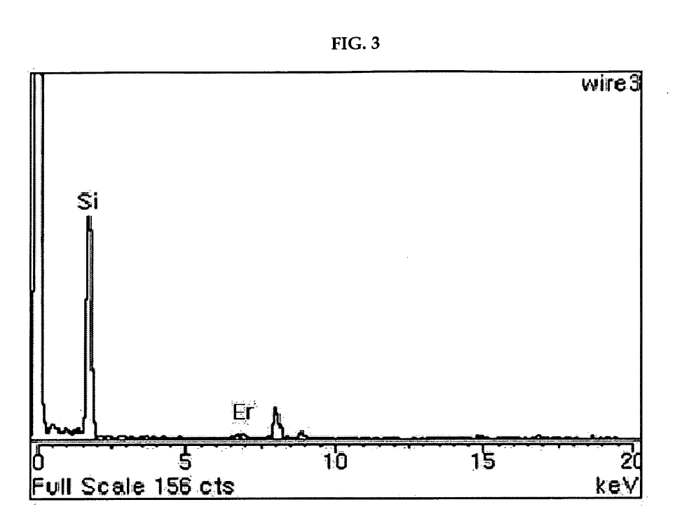

FIG. 3 is a graph showing the compositional analysis of the erbium-doped silicon nanowire.

When oxygen is flown on the substrate on which silicon nanowire 20 has grown at an elevated temperature (300-1,000° C.), silicon dioxide sheath 22 is formed as the silicon nanowire is oxidized. Resultantly, nanowire in which silicon is enclosed by silicon dioxide is obtained. This silicon dioxide sheath forms microcavity on the silicon nanowire and offers quantum confinement and photon amplification effects.

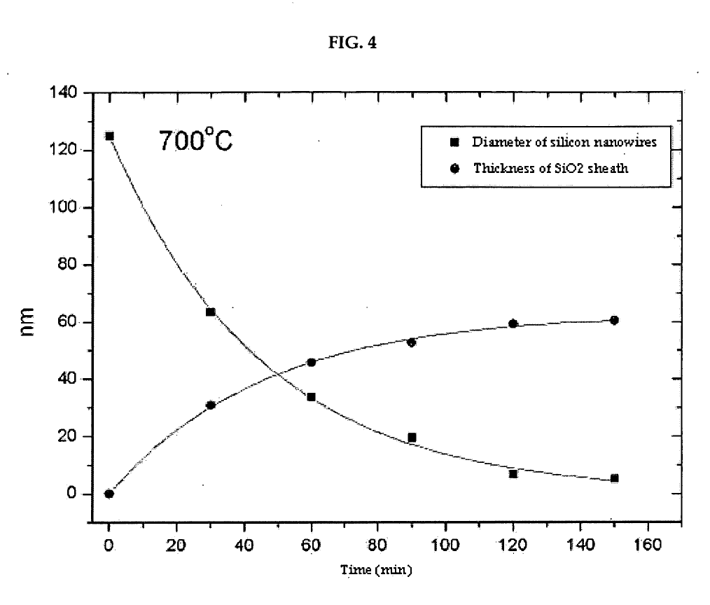

The diameter of the silicon nanowire can be controlled by the oxidization temperature and oxidization time (see FIG. 4). If the diameter of the inside silicon approaches 10 nm or less, the silicon has a quasi direct band gap property by the quantum confinement effect [Science, 287, 1471, 2000], and therefore becomes suitable for preparing an optoelectronic device. The silicon nanowire of the present invention has a diameter of less than 10 nm, and thus has the quasi direct band gap property by the quantum confinement.

Insulating film 30 supports silicon nanowire 20 and offers insulation in the p-n junction circuit structure. The insulating film may be formed on the substrate on which the nanowire has grown by a variety of methods. For example, a polymer insulating film may be formed by spin coating and an oxide insulating film may be formed by sputtering. Specifically, the insulating film may be prepared by using SiO₂, Al₂O₃, or common positive or negative photoresist such as AZ 1512, AZ 1506, S PR, and AZ 5214.

After the insulating film has been formed, the substrate is dry-etched or wet-etched to expose a part of the silicon nanowire. Then, electrodes are formed by the common semiconductor manufacturing method.

The electrodes are first electrode 40 which is formed on the part of silicon nanowire 20, which is enclosed by the insulating film 30, has been exposed by etching and enables electrical connection with silicon nanowire 20; and second electrode 42 which is formed on one side of the substrate 10 and enables electrical connection of the exposed silicon nanowire 20 and the substrate 10.

The first and second electrodes may be selected from Ti/Au, Al or ITO (indium tin oxide) transparent electrodes.

The silicon optoelectronic device of the present invention comprises silicon nanowire having a diameter of less than 10 nm. Further, because it has a p-n junction interface, photons are generated effectively when an electric current is applied by the light-emission recombination at the p-n junction.

Because erbium is doped into the silicon nanowire and the silicon dioxide sheath encloses the silicon nanowire, the photons excite the erbium ions. As the excited erbium ions are relaxed, light having a wavelength of about 1.5 μm is emitted.

The present invention is characterized by doping the silicon nanowire with erbium or an erbium precursor and oxidizing it to form a silicon dioxide sheath on the surface. As the diameter of the silicon nanowire decreases by oxidization, it has the photoelectric transition property by the quantum confinement effect when an electric current is applied. Light thus generated excites and decays the doped erbium, and consequently the silicon nanowire of the present invention emits light having a wavelength of about 1.5 μm. As silicon dioxide sheath 22 is formed by oxidizing the surface of the silicon nanowire, microcavity is formed in the silicon nanowire. This microcavity contributes to amplification of the light emitted by excitation and decay of erbium.

Especially, the silicon nanowire of the present invention has the structure of an optical cable because it is enclosed by silicon dioxide, which has a small refractive index (n=1.45). Thus, light having a high intensity is emitted because of amplification by the quantum confinement effect and the Fabry-Perot cavity effect, which happens in the one-dimensional nano structure [Nature Materials, 1, 106-110, (2002), J. Phy. Chem. B, 107, 8721-8725 (2003)].

Hereinafter, the present invention is described in detail with reference to the following examples. However, the following examples are only for the understanding of the present invention and they should not be construed as limiting the scope of the present invention.

### EXAMPLES

### Example 1

Au was deposited on an n-type silicon substrate to a thickness of 2 nm. A mixture gas of SiCl₄ and H₂ and a small amount of BCl₃ were flown on the substrate at 700° C. for 30 minutes in a reactor. In doing so, a small amount of ErCl₃ was positioned at about 3 cm in front of the substrate to dope erbium. O₂ was flown on the resultant silicon substrate, on which nanowire had grown, was oxidized at 500° C. for 8 hours to obtain silicon nanowire having a diameter of about 5 nm and enclosed by a silicon dioxide sheath.

FIG. 5 is a transmission electron micrograph of the obtained silicon nanowire. The diameter of the silicon nanowire was 5 nm.

A common photoresist was coated on the substrate, on which the silicon nanowire had grown, as insulating polymer by spin coating to form an insulating film. The silicon nanowire was exposed by plasma etching and the electrode component (Ti/Au) was deposited by electron beam deposition.

FIG. 6 is the light emission spectrum obtained by applying an electric current to the optoelectronic device prepared in Example 1. As seen in the figure, the optoelectronic device of the present invention emitted light having a wavelength of about 1.5 μm.

### Example 2

Silicon nanowire was grown in the same manner of Example 1. The surface of the silicon nanowire was coated with erbium by the sol-gel method using ErCl₃ as starting material. Then, heat treatment was performed under a H₂ atmosphere at 500° C. for 10 minutes. Oxidization was performed in the same manner of Example 1. The resultant optoelectronic device emitted light having a wavelength of about 1.5 μm.

As apparent from the above description, light having a wavelength of about 1.5 μm can be emitted effectively by oxidizing erbium-doped silicon nanowire to form a silicon dioxide sheath. Because the light can be amplified, it can be utilized in silicon optoelectronic devices.

In addition, because the optoelectronic device of the present invention is made of silicon, it is expected to contribute to cost reduction of optoelectronic devices.

While the present invention has been described in detail with reference to the preferred embodiments, those skilled in the art will appreciate that various substitutions and modifications can be made thereto without departing from the spirit and scope of the present invention as set forth in the appended claims.

1. A silicon optoelectronic device comprising
a) an n-type or p-type semiconductor substrate;
b) silicon nanowire which is formed on one side of the substrate and is rendered conductive by a p-type or n-type dopant and erbium;
c) an insulating film which is formed on the substrate and encloses the silicon nanowire;
d) a first electrode which is formed on the silicon nanowire, a part of which has been exposed by etching, and enables electrical connection of the silicon nanowire; and
e) a second electrode which is formed on one side of the substrate and enables electrical connection of the exposed silicon nanowire and the substrate.

2. The silicon optoelectronic device of claim 1, wherein the substrate is made of Si, SiC, GaN or GaAs.

3. The silicon optoelectronic device of claim 1, wherein the dopant is B or P.

4. The silicon optoelectronic device of claim 1, wherein the silicon nanowire is enclosed by a silicon dioxide sheath.

5. The silicon optoelectronic device of claim 1, wherein the silicon nanowire has a diameter of less than 10 nm.

6. The silicon optoelectronic device of claim 1, wherein the silicon nanowire enclosed by the silicon dioxide sheath and acts as microcavities.

7. The silicon optoelectronic device of claim 1, wherein the insulating film is made of polymer, SiO₂ or Al₂O₃.

8. The silicon optoelectronic device of claim 1, wherein the first and second electrodes are Ti/Au, Al or ITO (indium tin oxide) transparent electrodes.

9. A method for preparing a silicon optoelectronic device comprising the steps of
a) depositing Au on an n-type or p-type semiconductor substrate and flowing a silicon-containing precursor on the substrate at 400-1,000° C. to form silicon nanowire;
b) doping a p-type or n-type dopant and erbium or a precursor thereof into the silicon nanowire to offer conductivity;
c) oxidizing the silicon nanowire at 300-1,000° C. to form a silicon dioxide sheath on the surface of the silicon nanowire;
d) forming an insulating film on the substrate, on which the silicon nanowire has been formed, enclosing the silicon nanowire;
e) etching the substrate to expose a part of the silicon nanowire; and
f) forming a first electrode and a second electrode to enable electrical connection of the substrate and the exposed silicon nanowire.

10. The method for preparing a silicon optoelectronic device of claim 9, wherein the erbium precursor is ErCl₃.

11. The method for preparing a silicon optoelectronic device of claim 9, wherein the doping of erbium is performed by adding erbium or an erbium precursor during the formation of the silicon nanowire.

12. The method for preparing a silicon optoelectronic device of claim 9, wherein the doping of erbium is performed by a method selected from the group consisting of wet method, sol-gel method, coprecipitation, chemical deposition, laser abrasion and sputtering using erbium or an erbium precursor after the silicon nanowire has been formed.

13. The method for preparing a silicon optoelectronic device of claim 9, wherein the etching of the substrate is performed by wet etching or dry etching.
